(19) United States
(12) Patent Application Publication
(10) Pub. No.: US 2013/0256650 A1
(43) Pub. Date: Oct. 3, 2013

(54) SEMICONDUCTOR DEVICE AND FABRICATION METHOD THEREOF

(71) Applicants: Chih-Chung Yang, Taipei (TW); Horng-Shyang Chen, Taipei (TW); Shao-Ying Ting, Taipei (TW); Che-Hao Liao, Taipei (TW); Chih-Yen Chen, Taipei (TW); Chieh Hsieh, Taipei (TW); Hao-Tsung Chen, Taipei (TW); Yu-Feng Yao, Taipei (TW); Dong-Ming Yeh, Taipei (TW)

(72) Inventors: Chih-Chung Yang, Taipei (TW); Horng-Shyang Chen, Taipei (TW); Shao-Ying Ting, Taipei (TW); Che-Hao Liao, Taipei (TW); Chih-Yen Chen, Taipei (TW); Chieh Hsieh, Taipei (TW); Hao-Tsung Chen, Taipei (TW); Yu-Feng Yao, Taipei (TW); Dong-Ming Yeh, Taipei (TW)

(73) Assignee: NATIONAL TAIWAN UNIVERSITY, Taipei (TW)

(21) Appl. No.: 13/481,856

(22) Filed: May 27, 2012

(30) Foreign Application Priority Data
Apr. 3, 2012 (TW) 101111864

(51) Int. Cl. H01L 33/28; H01L 33/34; H01L 33/32; H01L 33/26

(52) U.S. Cl. 257/43; 438/46; 257/77; 257/76; 257/103; 257/E33.023; 257/E33.019; 257/E33.015

(57) ABSTRACT

A semiconductor device and fabrication method thereof are provided, wherein the fabrication method of the semiconductor device includes the following steps. Forming a semiconductor layer on a substrate, wherein the semiconductor layer has a top surface and a bottom surface that is opposite to the top surface. The bottom surface is in contact with the substrate, and the top surface has a plurality of pits, the pits are extended from the top surface toward the bottom surface. Preparing a solution, wherein the solution includes a plurality of nanoparticles. Filling the nanoparticles into the pits. Forming a conducting layer on the semiconductor layer after filling the nanoparticles into the pits.

### CROSS-REFERENCE TO RELATED APPLICATION

This application claims the priority benefit of Taiwan application serial no. 101111864, filed on Apr. 3, 2012. The entirety of the above-mentioned patent application is hereby incorporated by reference herein and made a part of this specification.

### BACKGROUND OF THE INVENTION

1. Field of the Invention

This invention relates to a semiconductor device and a fabrication method thereof.

2. Description of Related Art

With the development of optoelectronic technology in the present days, the fabrication and application of the semiconductor device has grown maturely. Devices such as the optoelectronic devices and the electronic devices are all fabricated based on semiconductor process, hence the semiconductor process technique has become one of the key issues of high-technology development.

The structure of a common semiconductor device includes a substrate, and the substrate is disposed with at least a semiconductor layer and a conducting layer thereon. During the process of forming a semiconductor layer between the substrate and the conducting layer, threading dislocation is generated in the semiconductor layer of the fabricated semiconductor device due to lattice mismatch between the semiconductor layer and the substrate. As shown in FIG. 1, a threading dislocation L is a long defect generated due to lattice mismatch within the semiconductor layer. As shown in FIG. 2, a threading dislocation L (long defect) is extended upwardly from the defect structure within the semiconductor layer, forming a pit V on the top surface of the semiconductor layer. Since the material of the conducting layer is filled into the pit V while forming the conducting layer, current leakage is generated within the semiconductor device, hence influences the device performance of the semiconductor device.

### SUMMARY OF THE INVENTION

The invention provides a fabrication method of semiconductor device, for fabricating a semiconductor device with good device performance.

The invention provides a semiconductor device with good device performance.

A fabrication method of semiconductor device, which includes the following steps. Forming a semiconductor layer on a substrate, wherein the semiconductor layer has a top surface and a bottom surface that is opposite to the top surface. The bottom surface is in contact with the substrate, and the top surface has a plurality of pits, the pits are extended from the top surface toward the bottom surface. Preparing a solution, wherein the solution includes a plurality of nanoparticles. Filling the nanoparticles into the pits, as to complete the fabrication of a semiconductor device. Forming a conducting layer on the semiconductor layer after filling the nanoparticles into the pits.

The invention also provides a semiconductor device, which includes a substrate, a semiconductor layer, a plurality of nanoparticles and a conducting layer, wherein the semiconductor layer has a top surface and a bottom surface that is opposite to the top surface, the bottom surface is in contact with the substrate, the top surface has a plurality of pits, the pits are extended from the top surface toward the bottom surface. A plurality of nanoparticles are filled into the pits. The conducting layer is disposed on the semiconductor layer, and the conducting layer and the substrate are respectively located at the two opposite sides of the semiconductor layer.

In an embodiment of the invention, the material of said nanoparticles includes silicon dioxide, silicone nitride, titanium dioxide, polystyrene (PS) or polymer.

In an embodiment of the invention, the diameters of said nanoparticles are between 2 nm to 100 nm.

In an embodiment of the invention, said solution further includes alcohols or organic solvent.

In an embodiment of the invention, said method of filling the nanoparticles into the pits includes placing the substrate having a disposed semiconductor layer in the solution, thereby filling the nanoparticles into the pits.

In an embodiment of the invention, regarding said fabrication method of the semiconductor device, wherein the semiconductor layer includes an undoped semiconductor layer, a first type doped semiconductor layer, a light-emitting layer and a second type doped semiconductor layer.

In an embodiment of the invention, said semiconductor layer includes an undoped semiconductor layer, a first type doped semiconductor layer, a second type doped semiconductor layer and a light-emitting layer. The undoped semiconductor layer is disposed on the substrate. The first type doped semiconductor layer is disposed on the substrate, and the first type doped semiconductor layer is located between the conducting layer and the undoped semiconductor layer. The second type doped semiconductor layer is disposed on the substrate, and the second type doped semiconductor layer is located between the conducting layer and the first type doped semiconductor layer. The light-emitting layer is disposed between the first type doped semiconductor layer and the second type doped semiconductor layer.

In an embodiment of the invention, said method of forming a semiconductor layer on the substrate includes metal organic chemical vapor deposition (MOCVD), molecular beam epitaxy (MBE), sputtering, evaporation, pulsed laser deposition (PLD), vapor phase epitaxy (VPE) or liquid phase epitaxy (LPE).

In an embodiment of the invention, said substrate includes sapphire substrate, silicon substrate, copper substrate or silicon carbide (SiC) substrate.

In an embodiment of the invention, the material of the said semiconductor layer includes zinc oxide (ZnO), cadmium zinc oxide (CdZnO), magnesium zinc oxide (MgZnO), cadmium magnesium zinc oxide (CdMgZnO), gallium nitride (GaN), aluminum nitride (AlN), aluminum gallium nitride (AlGaN), indium nitride (InN), indium gallium nitride (InGaN), indium aluminum nitride (InAlN) or aluminum indium gallium nitride (AlInGaN).

In an embodiment of the invention, the material of said conducting layer includes Au, Ag, Ni, Ti, Al, Cr, Pt, indium tin oxide (ITO), aluminum zinc oxide (AZO), gallium zinc oxide (GZO) or the mixture of above materials.

Base on the above, by filling the nanoparticles into the pits within the semiconductor layer, the conductive material of the conducting layer is prevented from filling into said pits as to reduce current leakage for improving the optoelectronic characteristics of the semiconductor device.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional transmission electron microscopy (TEM) image of a threading dislocation.

FIG. 2 is a plan-view scanning electron microscopy (SEM) image of a threading dislocation forming the pit on the top surface of the semiconductor layer.

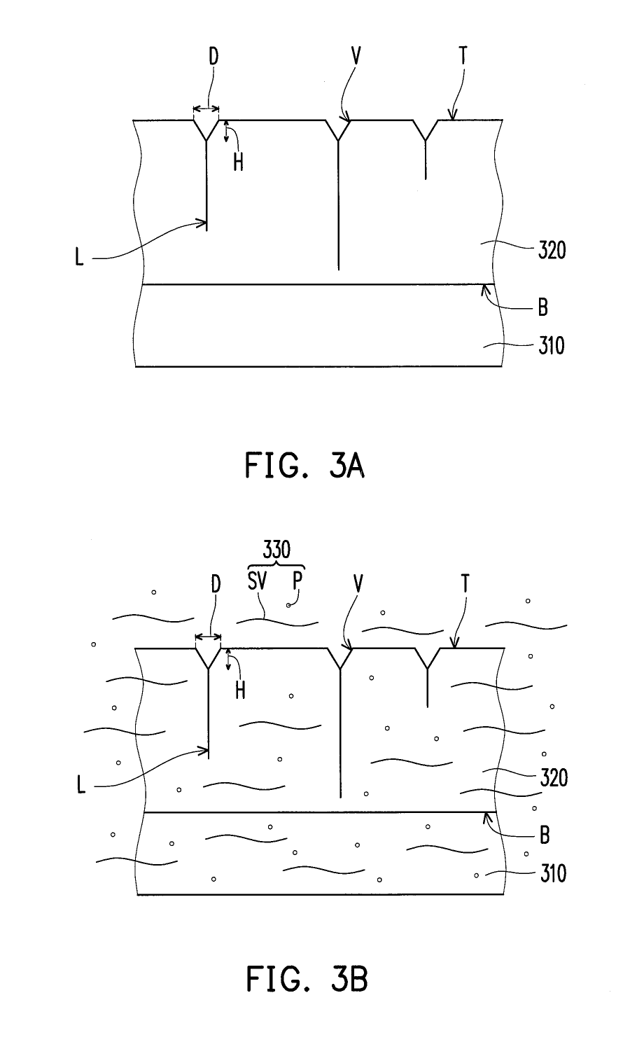

FIG. 3A to FIG. 3D are cross-sectional flow charts illustrating a fabrication of a semiconductor device according to an embodiment of the invention.

FIG. 4 is a cross-sectional view illustrating a semiconductor device according to an example of the invention.

FIG. 5 is a SEM image of the pit filled with the nanoparticles.

FIG. 6 is a device performance curve diagram of the semiconductor devices of the comparative example and the example according the invention.

### DESCRIPTION OF THE EMBODIMENTS

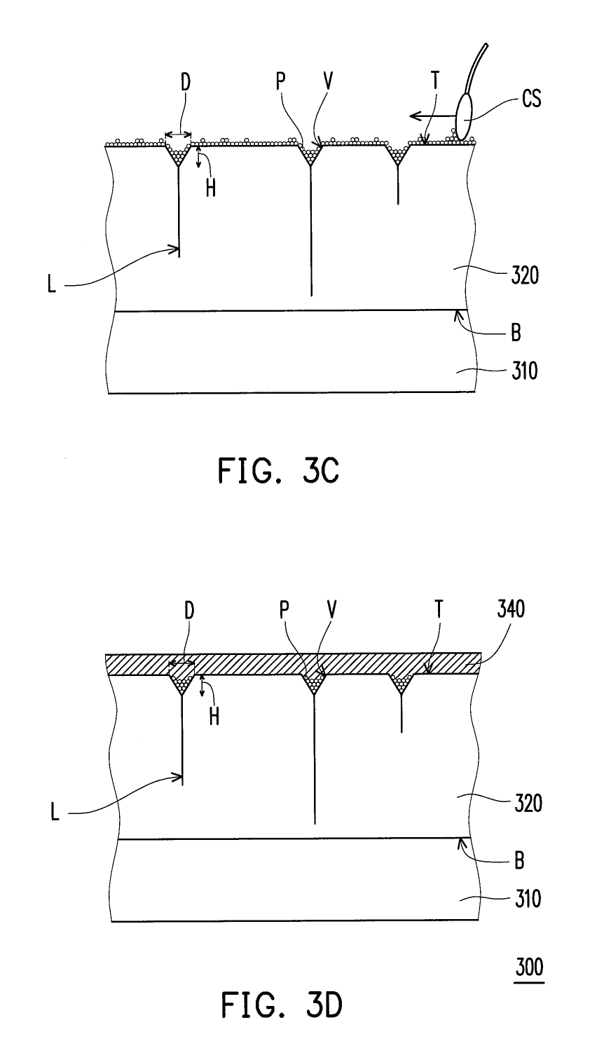

FIG. 3A to FIG. 3D are cross-sectional flow charts illustrating a fabrication of a semiconductor device according to an embodiment of the invention. Referring to FIG. 3A, first, forming a semiconductor layer 320 on a substrate 310, wherein the semiconductor layer 320 has a top surface T and a bottom surface B that is opposite to the top surface T, and the bottom surface B is in contact with the substrate 310.

The semiconductor layer 320 may be formed on the substrate 310 through methods such as physical vapor deposition (PVD), chemical vapor deposition (CVD) or epitaxy. Specifically, the semiconductor layer 320 may be formed on the substrate 310 through methods such as evaporation, sputtering, metal organic chemical vapor deposition, molecular beam epitaxy, pulsed laser deposition, vapor phase epitaxy or liquid phase epitaxy.

The substrate 310 may be a sapphire substrate, a silicon substrate, a copper substrate, a silicon carbide substrate or any substrate suitable of forming a semiconductor layer thereon. The material of the semiconductor layer may be zinc oxide (ZnO), cadmium zinc oxide (CdZnO), magnesium zinc oxide (MgZnO), cadmium magnesium zinc oxide (CdMgZnO), gallium nitride (GaN), aluminum nitride (AlN), aluminum gallium nitride (AlGaN), indium nitride (InN), indium gallium nitride (InGaN), indium aluminum nitride (InAlN), aluminum indium gallium nitride (AlInGaN) or other materials having semiconductor property or the mixture of above said materials.

In the present embodiment, although the semiconductor layer 320 is only illustrated as a single layer structure, practically, the semiconductor layer 320 may have additional semiconductor layers thereon based on different requirements. In other words, the semiconductor layer in other embodiments may also be a layered structure.

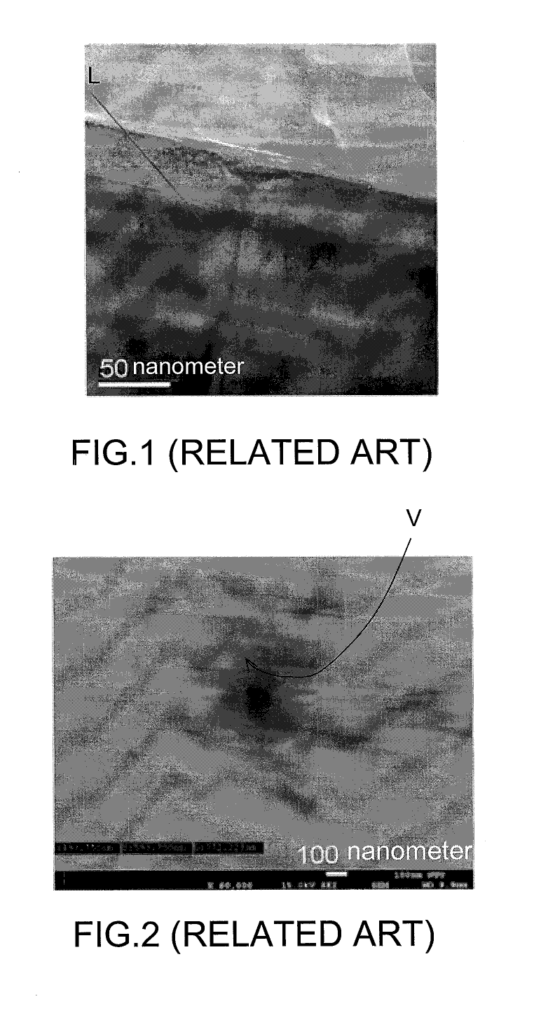

Because the lattice constant of the substrate 310 and that of the semiconductor layer 320 are different, when the semiconductor layer 320 is formed on the substrate 310, the lattice mismatch between the substrate 310 and the semiconductor layer 320 may cause threading dislocations within a structure of the formed semiconductor layer 320. Herein, a threading dislocation refers to the structure defect generated by the lattice mismatch within the structure of the semiconductor layer 320. A threading dislocation L (long defect) is extended upwardly from the structure defect within the semiconductor layer 320, and forming a pit V on the top surface T of the semiconductor layer 320, as shown in the TEM (Transmission Electron Microscopy) image of FIG. 1. From the viewpoint of the structure, the threading dislocations L may also refer to as the top surface T of the semiconductor layer 320 having the pits V, wherein each of the pits V is extended toward the bottom surface B, and the pits V have a depth H.

In addition, the degree of the lattice mismatch will be different with a different combination of the substrate 310 and the semiconductor layer 320, thereby changing the diameter D of the pits V on the top surface T and the depth H of the pits V that is extended toward the bottom surface B. Furthermore, the distribution density of the threading dislocation L within the structure of the semiconductor layer 320 or the planar density of the pits V on the top surface T of the semiconductor layer 320 may also be changed. Moreover, the diameter D of the pits V and the depth H of the pits V that is extended toward the bottom surface B may be different due to the changes of the process parameters and the process variations, even within the same structure of the semiconductor layer 320, as shown in FIG. 3A. Therefore, the present embodiment is not intended to limit the diameter D of the pits V, the depth H of the pits V that is extended toward the bottom surface B and the planer density of the pits V on the top surface.

Referring to FIG. 3B, preparing a solution 330, wherein the solution 330 includes a plurality of nanoparticles P. The method of preparing the solution 330 is, for example, spreading the plurality of nanoparticles P in alcohols, organic solvent or other suitable solvent. The material of the nanoparticles P includes silicon dioxide, silicone nitride, titanium dioxide, polystyrene or polymer, diameters of the nanoparticles P are between 2 nm to 100 nm, and the shape of the nanoparticles P may be a sphere, a pillar or irregular shape. In the present embodiment, the solution 330 is composed by, for example, isopropanol SV and the nanoparticles P spread in the isopropanol SV, wherein the material of the nanoparticles P is silicon dioxide.

Next, placing the substrate 310 having the disposed semiconductor layer 320 in the solution 330, thereby filling the nanoparticles P into the pits V. In the present embodiment, the weight percentage of the nanoparticles P in the solution 330, for example, is 5 wt %, and the time for leaving the substrate 310 having the disposed semiconductor layer 320 in the solution 330, for example, is 8 hours. It is noted that, those skilled in the art may realize that, the time required for filling the nanoparticles P into the pits V is varied, based on the weight percentage of the nanoparticles P in the solution 330. Therefore, the present embodiment is not limited by the above conditions (that is, the weight percentage of the nanoparticles P in the solution 330 or the time for leaving the substrate 310 having the disposed semiconductor layer 320 in the solution 330).

Referring to FIG. 3C, removing the applied nanoparticles P on the top surface T of the semiconductor layer 320. In the present embodiment, method of removing the applied nanoparticles P on the top surface T is, for example, wiping the top surface T of the semiconductor layer 320 with a cotton swab CS. It is noted that, the filling condition (i.e. the distribution and the filling degree of the nanoparticles P in the pits V) of the nanoparticles in the pits V is varied due to the changes of the time for leaving the substrate 310 having the disposed semiconductor 320 in the solution 330. Therefore, the present embodiment is not intended to limit the distribution and the filling degree of the nanoparticles P in the pits V.

Referring to FIG. 3D, forming a conducting layer 340 on the top surface of the semiconductor layer 320 after filling the nanoparticles P into the pits V. In the present embodiment, the method of forming a conducting layer 340 on the top surface T of the semiconductor layer 320 may be, for example, forming the conducting layer 340 on the top surface T of the semiconductor layer 320 by using methods such as evaporation and sputtering. Wherein, the material of the conducting layer 340 is a conducting material, the conducting material may be Au, Ag, Ni, Ti, Al, Cr, Pt, indium tin oxide (ITO), aluminum zinc oxide (AZO), gallium zinc oxide (GZO), other conductive materials or the mixture of above materials. Further, the conducting layer 340 may be the above conducting material in a single-layer structure or a multi-layer structure. The initial fabrication of the semiconductor device 300 of the present embodiment is completed after the conducting layer 340 is formed. In particular, on practical applications, the conducting layer 340 may be used as a current spreading layer as well as an electrode layer, depending on the design criteria of the semiconductor device.

It is noted that, the present embodiment is not intended to limit the semiconductor layer to a single-layer structure or a multi-layer structure. Rather, it is aimed to emphasize that, by filling the nanoparticles P into the pits V before the conducting layer is formed, the conductive material may be prevented from filling into the pits V while forming the conducting layer 340 and to reduce current leakage. As a result, the device performance of the semiconductor device 300 may be improved.

It is worth mentioning that, the semiconductor device 300 formed by using the fabrication method of the present embodiment may be further fabricated to the optoelectronic devices or the high-power electronic devices. Wherein the optoelectronic devices may be, for example, a light emitting diode (LED), a solar cell, a photo-detector or a laser diode (LD), and the high-power electronic devices may be, for example, devices such as a field effect transistor (FET) or a high electron mobility transistor (HEMT).

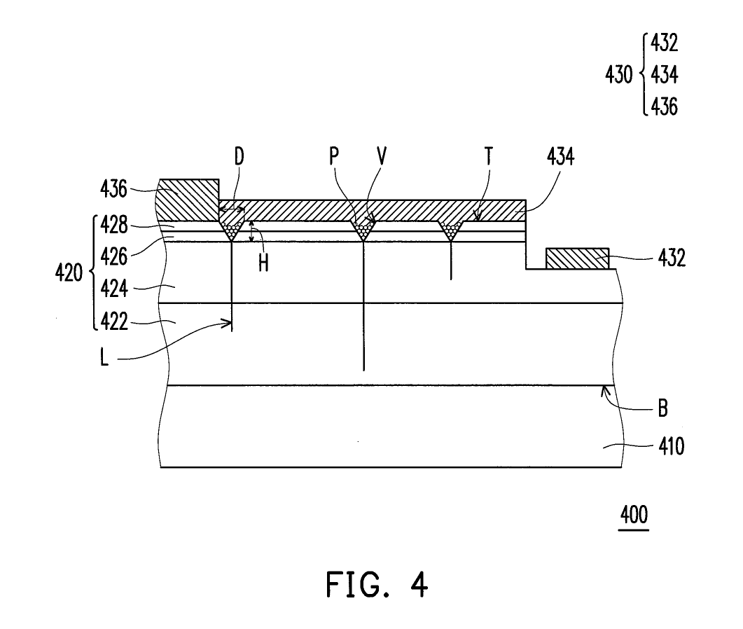

In order to clearly illustrate the effects that may be obtained from the device performance improved by filling the nanoparticles P into the pits V, an example accompanying FIG. 4 to FIG. 6 as reference is provided.

FIG. 4 is a cross-sectional view illustrating a semiconductor device according to an example of the invention. Referring to FIG. 4, the semiconductor device 400 of the present example is, for example, an LED including a substrate 410, a semiconductor layer 420 and a conducting layer 430, wherein the semiconductor layer 420 is located between the substrate 410 and the conducting layer 430, and the semiconductor layer 420 has a bottom surface B, and a top surface T that is opposite to the bottom surface B. The bottom surface B is in contact with the substrate 410, the top surface T has a plurality of pits V, and each of the pits V is extended toward the bottom surface B. In the present example, the substrate 410 is, for example, a sapphire substrate, and the semiconductor layer 420 is, for example, a gallium nitride compound or a zinc oxide related compound.

In the present example, the semiconductor layer 420 is a layered structure, including an undoped semiconductor layer 422, a first type doped semiconductor layer 424, a light-emitting layer 426 and a second type doped semiconductor layer 428. Wherein the undoped semiconductor layer 422 is disposed on the substrate 410, and the undoped semiconductor layer 422 is located between the substrate 410 and the conducting layer 430. The first type doped semiconductor layer 424 is disposed on the undoped semiconductor layer 422, and the first type doped semiconductor layer 424 is located between the conducting layer 430 and the undoped semiconductor layer 422. The second type doped semiconductor 428 is located between the conducting layer 430 and the first type doped semiconductor layer 424. The light-emitting layer 426 is located between the first type doped semiconductor layer 424 and the second type doped semiconductor layer 428. The material of the first type doped semiconductor layer 424 is, for example, a P-type gallium nitride. The material of the second type doped semiconductor layer 428 is, for example, a N-type zinc oxide. The material of the light-emitting layer 426 is, for example, a multiple quantum well with an alternately stacked structure of cadmium zinc oxide (CdZnO) and zinc oxide (ZnO).

In the present example, the method of forming the undoped semiconductor layer 422 and the first type doped semiconductor layer 424 on the substrate 410 is by using, for example, organic chemical vapor deposition, wherein the film thickness of the undoped semiconductor layer 422 is 2 micrometer and a film thickness of the first type doped semiconductor layer 424 is 1 micrometer. A method of forming the light-emitting layer 426 and the second type doped semiconductor layer 428 on the substrate 410 is by using, for example, molecular beam epitaxy, wherein the film thickness of the light-emitting layer 426 is 0.07 micrometer and a film thickness of the second type doped semiconductor layer 428 is 0.12 micrometer.

It is noted that, because the first type doped semiconductor layer 424, the light-emitting layer 426 and the second type doped semiconductor layer 428 are sequentially grown on the undoped semiconductor layer 422 having a plurality of threading dislocations L, during the process of growing the first type doped semiconductor layer 424, the light-emitting layer 426 and the second type doped semiconductor layer 428, the plurality of threading dislocations L will extend upwardly to an outer surface (that is, the top surface T of the semiconductor layer 420) of the second type doped semiconductor layer 428, simultaneously. Therefore, from the viewpoint of the structure, a plurality of pits V are generated on the outer surface of the second type doped semiconductor layer 428 after the fabrication of the said layered structure of the semiconductor layer 420 is completed.

Of course, under different process conditions and process variations, the structure defect generated by the threading dislocations L may also be generated by layers other than the undoped semiconductor layer 422, such that the pits V may have different diameter D, different depth H that is extended toward the bottom surface B and different planar density on the top surface T. Therefore, the present example is not intended to limit the diameter D of the pits V, the depth H of the pits V that is extended toward the bottom B and the planar density of the pits V on the top surface T.

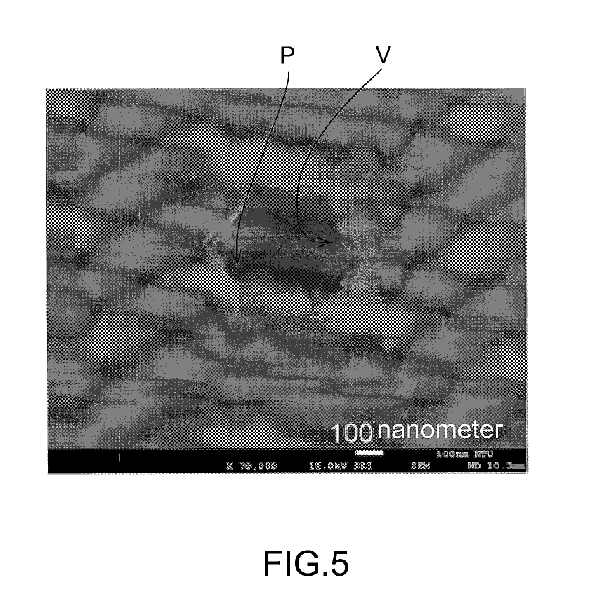

Next, before the current spreading layer 434 and the conducting layer 436 are formed, the pits V of the present example may be filled with the nanoparticles P by using the method of filling the nanoparticles P of above embodiment. FIG. 5 is an image observed by using SEM (Scanning electron microscopy), and it is obvious that the pit V of FIG. 5 is filled with nanoparticles P. Referring to FIG. 5, a diameter of the pit V is approximately 500 nm and diameters of the nanoparticles P are between 20 nm and 50 nm, and by filling the nanoparticles P into the pit V, the conductive material may be prevented from filling into the pit V while forming a current spreading layer 434 and the second electrode 436, and thus can reduce the current leakage. As a result, the device performance of the semiconductor device 400 may be improved.

In the present example, the conducting layer further includes a first electrode 432, a second electrode 436, and a current spreading layer 434 that is electrically connected to the second electrode 436. The second electrode 436 is disposed on a portion of the second type doped semiconductor layer 428, and the second electrode 436 and the light-emitting layer 426 are respectively located at the two opposite sides of the second type doped semiconductor layer 428. The current spreading layer 434 and the second electrode 436 are located at the same side of the second type doped semiconductor layer 428, and the current spreading layer 434 is disposed on the second type doped semiconductor layer 428, other than where the second electrode 436 is disposed. The first electrode 432 is disposed on a portion of the first type doped semiconductor layer 424, and the first electrode 432 and the substrate 410 are respectively located at the two opposite sides of the undoped semiconductor layer 422.

In the present example, the method of forming the current spreading layer 434, the first electrode 432 and the second electrode 436 may include the following steps. First, sequentially forming the undoped semiconductor layer 422, the first type doped semiconductor layer 424, the light-emitting layer 426 and the second type doped semiconductor layer 428 on the substrate 410. Next, by using a patterning process, patterning a thickness of a portion of the second type doped semiconductor 428, the light-emitting layer 426 and the first type doped semiconductor 424, thereby forming a mesa of the current spreading layer 434 and the second electrode 436 on the second type doped semiconductor layer 428 and the light-emitting layer 426, and exposing a portion of the first type doped semiconductor layer 424. Followed by forming the first electrode 432 and the second electrode 436 respectively on the first type doped semiconductor layer 424 and the second type doped semiconductor layer 428. Lastly, forming the current spreading layer 434 on the second type doped semiconductor 428, other than the area where the second electrode 436 is disposed. Materials of the current spreading layer 434, the first electrode 432 and the second electrode 436 are, for example, metal or other conductive materials or related laminated layers. In the present example, the materials of the current spreading layer 434 and the second electrode 436 are, for example, a metal stacked layer of Ti and Au, and the material of the first electrode, for example, is a metal stacked layer of Ni and Au.

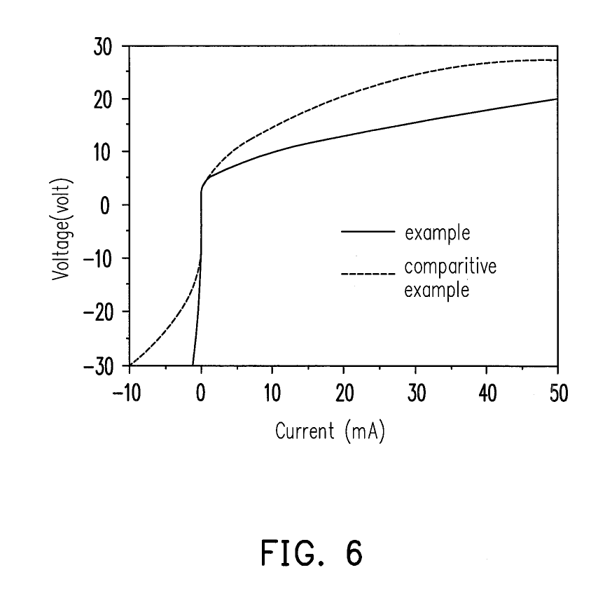

FIG. 6 is a performance curve diagram of relation between voltage and current in the semiconductor devices of the comparative example and the example, wherein the comparative example has similar structure to the example, their difference lies in where the pits of the semiconductor layered structure of the semiconductor device in the example are filled with the nanoparticles, and the pits of the semiconductor layered structure of the semiconductor device in the comparative example are not filled with the nanoparticles.

Referring to FIG. 6, when the voltage is applied to the semiconductor devices of the example and the comparative example, the pits of the semiconductor layered structure are filled with the nanoparticles before the current spreading layer is formed on the semiconductor device of the example. Therefore, by filling the nanoparticles into the pits within the semiconductor layered structure, the conductive material is prevented from filling into the pits during the forming process of the current spreading layer 434 and the second electrode 436. In this case, the semiconductor device that is filled with the nanoparticles (of the example) may sufficiently suppress current leakage caused by threading dislocations when the voltage is applied thereto, such that current may be effectively used for emission while flowing along the path between the first electrode and the second electrode, thereby improving the light emission efficiency. The comparison between the magnitude of the current leakage may be observed by applying a reverse voltage (the voltage with a negative value in FIG. 6). When the reverse voltage is applied to each of the semiconductor devices of the comparative example and the example, the semiconductor device of the example has a smaller current leakage (the current with negative value in FIG. 6). Therefore, by filling the nanoparticles into the pits within the semiconductor layered structure, the device performance of the semiconductor device may be effectively improved.

It is worth mentioning that, although the semiconductor layer of above example is a layered structure, but the invention is not limited thereto. In other examples, the semiconductor layer may also be a single layer structure. In addition, in the case where the semiconductor layer is a layered structure, the nanoparticles are filled into the pits after the semiconductor layered structure is formed and before the current spreading layer is formed, however, the invention is not limited thereto. In other embodiments, the steps of filling the nanoparticles may be performed on any layer of the semiconductor layered structure (including the undoped semiconductor layer, the first type doped semiconductor layer, the light-emitting layer and the second type doped semiconductor layer) before the current spreading layer is formed. For example, the nanoparticles may be filled into the pits after the first type doped semiconductor layer is formed, followed by the growths of the light-emitting layer and the rest of the layers. The semiconductor device formed with such architecture may have the same performance as the said embodiment and the said example. Meanwhile, the density of threading dislocation may be reduced in the growth of the following semiconductor layers, thereby obtaining a better crystal quality. In summary, the semiconductor device formed with such architecture may also have a better device performance.

In view of above, the invention provides a method, by filling the nanoparticles into the pits within the semiconductor layer, the conductive material is prevented from filling into the pits while forming the conducting layer. Such that, current leakage in the semiconductor device may be reduced, and the optoelectronic characteristics of the semiconductor device may be improved.

Although the disclosure have been described with reference to the above embodiments, it will be apparent to one of the ordinary skill in the art that modifications to the described embodiment may be made without departing from the spirit of the described embodiment. Accordingly, the scope of the disclosure will be defined by the attached claims not by the above detailed descriptions.

1. A fabrication method of semiconductor device, comprising:
forming a semiconductor layer on a substrate, wherein the semiconductor layer has a top surface and a bottom surface that is opposite to the top surface, the bottom surface is in contact with the substrate, and the top surface has a plurality of pits, the plurality of pits are extended from the top surface toward the bottom surface;
preparing a solution, wherein the solution comprises a plurality of nanoparticles;
filling the plurality of nanoparticles into the plurality of pits; and
forming a conducting layer on the semiconductor layer after the plurality of nanoparticles are filled into the plurality of pits, wherein the conducting layer is in contact with the top surface.

2. The fabrication method of semiconductor device according to claim 1, wherein the material of the plurality of nanoparticles comprises silicon dioxide, silicon nitride, titanium dioxide, polystyrene or polymer.

3. The fabrication method of semiconductor device according to claim 1, wherein the diameters of the plurality of nanoparticles are between 2 nm to 100 nm.

4. The fabrication method of semiconductor device according to claim 1, wherein the solution further comprises alcohol or organic solvent.

5. The fabrication method of semiconductor device according to claim 1, wherein the method of filling the plurality of nanoparticles into the plurality of pits, comprising:
placing the substrate having a disposed semiconductor layer in the solution, for filling the plurality of nanoparticles into the plurality of pits.

6. The fabrication method of semiconductor device according to claim 1, wherein the semiconductor layer comprises an undoped semiconductor layer, a first type doped semiconductor layer, a light-emitting layer and a second type doped semiconductor layer.

7. The fabrication method of semiconductor device according to claim 1, wherein the method of forming the semiconductor layer on the substrate comprises metal organic chemical vapor deposition, sputtering, molecular beam epitaxy, pulsed laser deposition, vapor phase epitaxy, liquid phase epitaxy or evaporation.

8. The fabrication method of semiconductor device according to claim 1, wherein the substrate comprises sapphire substrate, silicon substrate, copper substrate or silicon carbide substrate.

9. The fabrication method of semiconductor device according to claim 1, wherein the material of the semiconductor layer comprises zinc oxide (ZnO), cadmium zinc oxide (CdZnO), magnesium zinc oxide (MgZnO), cadmium magnesium zinc oxide (CdMgZnO), gallium nitride (GaN), aluminum nitride (AlN), aluminum gallium nitride (AlGaN), indium nitride (InN), indium gallium nitride (InGaN), indium aluminum nitride (InAlN), aluminum indium gallium nitride (AlInGaN).

10. The fabrication method of semiconductor device according to claim 1, wherein the material of conducting layer is conductive material, comprising: Au, Ag, Ni, Ti, Al, Cr, Pt, indium tin oxide (ITO), aluminum zinc oxide (AZO), gallium zinc oxide (GZO), or the mixture or layered structure of above materials.

11. A semiconductor device, comprising:
a substrate;
a semiconductor layer, disposed on the substrate, the semiconductor layer has a top surface and a bottom surface that is opposite to the top surface, wherein the bottom surface is in contact with the substrate, and the top surface has a plurality of pits, the plurality of pits are extended from the top surface toward the bottom surface;
a plurality of nanoparticles, filled into the plurality of pits; and
a conducting layer, disposed on the semiconductor layer, and the conducting layer and the substrate are respectively located at the two opposite sides of the semiconductor layer, wherein the conducting layer is in contact with the top surface.

12. The semiconductor device according to claim 11, wherein the material of the plurality of nanoparticles comprises silicon dioxide, silicon nitride, titanium dioxide, polystyrene or polymer.

13. The semiconductor device according to claim 11, wherein the diameters of the plurality of nanoparticles are between 2 nm to 100 nm.

14. The semiconductor device of claim 11, wherein the semiconductor layer comprises:
An undoped semiconductor layer, disposed on the substrate;
a first type doped semiconductor layer, disposed on the substrate, and the first type doped semiconductor layer is located between the conducting layer and the undoped semiconductor layer;
a second type doped semiconductor layer, disposed on the substrate, and the second type doped semiconductor layer is located between the conducting layer and the first type doped semiconductor layer; and
a light-emitting layer, disposed between the first type doped semiconductor layer and the second type doped semiconductor layer.

15. The semiconductor device according to claim 11, wherein the substrate comprises sapphire substrate, silicon substrate, copper substrate or silicon carbide substrate.

16. The semiconductor device according to claim 11, wherein the material of the semiconductor layer comprises zinc oxide (ZnO), cadmium zinc oxide (CdZnO), magnesium zinc oxide (MgZnO), cadmium magnesium zinc oxide (CdMgZnO), gallium nitride (GaN), aluminum nitride (AlN), aluminum gallium nitride (AlGaN), indium nitride (InN), indium gallium nitride (InGaN), indium aluminum nitride (InAlN), aluminum indium gallium nitride (AlInGaN).

17. The semiconductor device according to claim 11, wherein the material of conducting layer is conductive material, comprising: Au, Ag, Ni, Ti, Al, Cr, Pt, indium tin oxide (ITO), aluminum zinc oxide (AZO), gallium zinc oxide (GZO), or the mixture of above materials.
